(19) United States
(12) Patent Application Publication
(10) Pub. No.: US 2009/0289284 A1
(43) Pub. Date: Nov. 26, 2009

(54) High shrinkage stress silicon nitride (SiN) layer for NFET improvement

(75) Inventors: Luona Goh, Singapore (SG); Jingze Tian, Singapore (SG); Wei Lu, Singapore (SG); Mei Sheng Zhou, Singapore (SG)

Correspondence Address: DOCKET CLERK, P.O. DRAWER 800889, DALLAS, TX, 75380, US

(73) Assignee: Chartered Semiconductor Manufacturing, Ltd.

(21) Appl. No.: 12/154,605

(22) Filed: May 23, 2008

(51) Int. Cl. H01L 29/78; H01L 21/3105

(52) U.S. Cl. 257/288; 438/759; 257/E21.241

(57) ABSTRACT

A method (and semiconductor device) of forming a high shrinkage stressed silicon nitride layer for use as a contact etch stop layer (CESL) or capping layer in a stress management technique (SMT) provides increased tensile stress to a channel of an nFET device to enhance carrier mobility. A spin-on polysilazane-based dielectric material is applied to a semiconductor substrate and baked to form a film layer. The film layer is cured to remove hydrogen from the film which causes shrinkage in the film when it recrystallizes into silicon nitride. The resulting silicon nitride stressed layer introduces an increased level of tensile stress to the transistor channel region.

### TECHNICAL FIELD

The present disclosure relates generally to devices and methods of fabrication of semiconductor devices, and more particularly to the fabrication of field-effect transistors (FETs) having a high shrinkage stress silicon nitride region for stress and performance enhancement.

### BACKGROUND

In complementary metal-oxide semiconductor (CMOS) devices, some efforts and improvements have been aimed at enhancing carrier mobility. Among these, forming a stressed silicon channel is a known practice that enhances performance of MOS devices. In addition to substrate-induced strain (e.g., forming strained silicon on a relaxed silicon-germanium (SiGe) substrate), process-induced strain may be created utilizing a contact etch stop layer (CESL), stress management techniques (SMT) and embedded silicon-germanium in the source/drain regions.

N-type MOS (nMOS) device performance is improved by tensile stress in the channel region, while P-type MOS (pMOS) device performance is improved by compressive stress in the channel region. In one method, stresses are applied by depositing a stress layer, such as a CESL, on the gate structure and source/drain regions of the MOS device.

With reference to FIG. 1, a conventional nMOS device 10 and a conventional pMOS device 20 are illustrated with a typical CESL structure 4 formed on a substrate 2 and separated by an isolation structure 5. The CESL structure 4 includes a tensile stressed CESL 4a formed over the nMOS device 10 and a compressive stressed CESL 4b formed over the pMOS device 20. To form the CESLs 4a and 4b with different types of stresses, two different processes are performed, with each process including its own CESL deposition, photolithography and etch steps. As a result, the cost for introducing different stresses with known deposition techniques is relatively high. This is commonly referred to as dual stress liner (DSL) technology.

In other solutions, a single tensile stressed CESL is formed over both nMOS and pMOS devices (not shown). To recover pMOS performance, additional processing steps must be performed. For example, the CESL may be removed locally (over the pMOS devices) but this requires additional processing steps. Alternatively, it has been proposed to perform ion implantation or plasma treatment on the CESL portion over the pMOS device thereby causing a change of the stress (lowering the tensile stress) in that region.

Though other materials may be used, silicon nitride (SiN) is the most commonly utilized material for a CESL and is formed by chemical vapor deposition (CVD) techniques, including plasma induced CVD (PECVD). SiN exhibits a wide range of capability for stress tuning—from approximately tensile 1.2 GigaPascals (GPA) to compressive 3.5 GPA.

In an effort to increase tensile stress beyond this range, external treatment of the CESL is usually required. In one known treatment, the SiN is deposited by CVD with a high amount of hydrogen bonding in the film (e.g., Si—H). This deposited film is relatively porous and possesses a high wet etch rate. After deposition, the H-rich SiN film is subjected to a nitrogen gas (N2) treatment or ultra-violet (UV) treatment for film densification. During this step, a substantial number of the Si—H weak bonds are removed and the post-treated SiN experiences shrinkage. This typically increases tensile stress up to about 1.7 GPA.

In addition to formation of a CESL, the channel region may be locally stressed/strained through a stress memorization technique (SMT) resulting in performance improvements for nMOS devices. In this approach, the source/drain (S/D) substrate area and polysilicon gate structure are amorphized by S/D and extension implantation of a dopant. Conventional dopant activation annealing is performed after the deposition of a tensile stressor capping layer, such as silicon nitride. The stress effect is transferred from the silicon nitride stressor layer to the channel during the annealing process and the re-crystallization of the S/D and poly gate layers “memorizes” the stress. This stress is retained even after the removal of the silicon nitride capping layer. A thick capping layer may be used to increase the stress level since this layer is usually subsequently removed.

In another more recently proposed technique, either with or without a CVD oxide buffer layer, the interaction of silicon nitride properties, dopant activation and poly-silicon gate mechanical stress are utilized to maintain (or possibly enhance) nFET performance with little or no pMOS performance degradation. This technique utilizes a well-known CVD process for the formation of the SiN layer.

One problem with the foregoing prior art methods and devices is that the relative tensile stress provided or exhibited by the deposited silicon nitride layer (either CESL or capping layer in an SMT) is generally limited to the foregoing ranges and requires complex processing steps.

Accordingly, there is a need for an improved fabrication process (and resulting devices) that increases the amount of tensile stress applied (or applies it in a less complex process) or introduced to the channel region to enhance transistor performance.

### SUMMARY

In accordance with one embodiment, there is provided a method of forming a semiconductor structure. The method includes providing a substrate and forming a stressed layer overlying the substrate for applying tensile stress to a channel region of an n-type field effect transistor (FET). Forming the stressed layer includes spin-on deposition of a dielectric material on the substrate, heating the dielectric material to form a dielectric film, and curing the dielectric film to shrink the dielectric film thereby forming the stressed layer.

In accordance with another embodiment, there is provided a semiconductor substrate having one or more field effect transistors (FETs). The substrate includes a first n-type FET having a source region, a drain region and a gate structure, and a stressed film overlying the source region, the drain region and the gate structure, the stressed film imparting a tensile stress of at least about 1.7 Gpa within a channel region extending between the source region and the drain region.

In yet another embodiment, there is provided a method of forming a stressed layer for generating tensile stress within a channel region of a field-effect transistor (FET) in a semiconductor structure. The method includes spinning on a dielectric material over a gate structure, a source region and a drain region of a FET, heating the dielectric material to form a dielectric film, and curing the dielectric film to shrink the dielectric film thereby forming the stressed layer.

Other technical features may be readily apparent to one skilled in the art from the following figures, descriptions, and claims.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects, and in which:

FIG. 1 is a cross-sectional view illustrating a prior art semiconductor device having a contact etch stop layer; and

FIGS. 2A-2B are cross-sectional views illustrating various steps of a method or process of forming a stressed layer (such as a contact etch stop layer or capping layer) in accordance with the present disclosure.

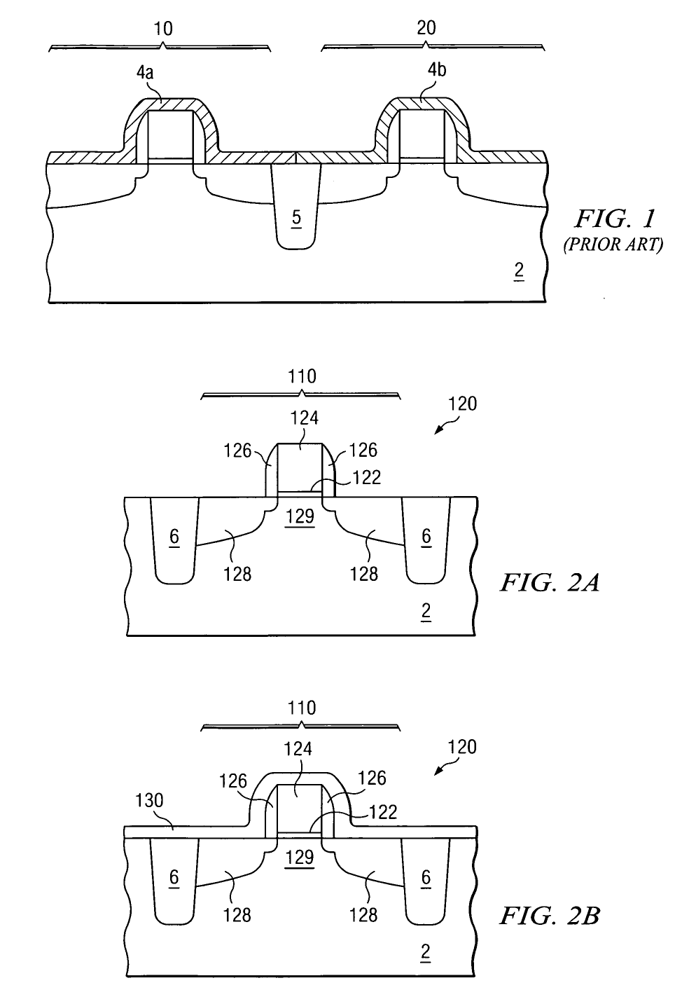

### DETAILED DESCRIPTION

Now referring to FIGS. 2A-2B, there are shown cross-sectional views of a process for forming a contact etch stop layer (CESL) in accordance with this disclosure. With specific reference to FIG. 2A, there is shown an initial structure including a substrate 2. Substrate 2 may be formed of common substrate materials such as silicon, SiGe, stressed silicon on SiGe, silicon on insulator (SOI), silicon germanium on insulator (SGOI), germanium on insulator (GOI), and the like, or other suitable semiconductor substrate materials, now known or later developed. The substrate 2 may include silicon (e.g., n-type, p-type, or no type) provided in a single well or twin-well process, and may further include an epitaxial layer.

Substrate 2 is illustrated having at least one device region 110 used for forming a field effect transistor (FET), such as a metal-oxide-semiconductor (MOS) device. The substrate 2 may include one or more isolation structures 6 well-known in the art. As will be appreciated, the device region 110 may be used to form an n-type FET (nFET) or a p-type FET (pFET) and more than one FET may be formed on the substrate 2. For the purposes of describing the present disclosure, the device region 110 will be described with respect to an nFET structure.

The device region 110 includes an nFET structure 120 formed thereon which includes a gate dielectric layer 122, a gate electrode layer 124, sidewall spacers 126, source/drain (S/D) regions 128 and a channel region 129 beneath the gate structure extending between the S/D regions 128. As is well known in the art, the gate dielectric 122 is formed on the substrate 2 and may be formed of silicon oxide or other materials having high dielectric constants (k values). The gate electrode layer 124 may include polysilicon, metals, metal nitrides, metal silicides, and the like, and is formed on the gate dielectric 122. The S/D regions 128 are formed by implanting appropriate impurities into substrate 2. These regions 128 may be recessed in or elevated above the substrate 2, and any subsequently formed stress-inducing layer (hereafter described) will may also be recessed or elevated.

Though not shown, one or more silicide layers may be formed on the gate electrode 124 and/or S/D regions 128. As is known in the art, in the salicide process for forming silicide regions, a metal layer is formed by first depositing a thin layer of metal, such as cobalt, nickel, titanium, and the like, over the desired area and then annealing to form silicide regions between the deposited metal and the underlying exposed silicon regions.

The nFET structure 120 may be formed in accordance with any prior art (or later developed) processes or techniques, including plasma enhanced chemical vapor deposition (PECVD), low pressure chemical vapor deposition (LPCVD), rapid thermal chemical vapor deposition (RTCVD), atomic layer deposition (ALD), physical vapor deposition (PVD), etching, implantation, thermal processes, and the like, all well-known in the art of fabricating MOS devices.

Now referring to FIG. 2B, there is illustrated the formation of a stressed layer 130 on the nFET structure 120. Stressed layer 130 may be a contact etch stop layer (CESL) or combination of CESL and other layers, regardless of whether the layer(s) perform an etch stop function. In accordance with the one embodiment of the present disclosure, the stressed layer 130 is formed of silicon nitride (SiₓN_{y}). In another embodiment (not shown), the stressed layer 130 may be formed atop a buffer layer (of oxide, nitride, oxy-nitride or other dielectric material(s)) disposed between the S/D contact regions 128 and silicon nitride layer. The stressed layer 130 may have a thickness in the range of about 250 to about 1500 Angstroms (about 25 to about 150 nm). In other embodiments, the thickness is less than about 1000 Angstroms or less than about 750 Angstroms, and may even be on the order of 500 Angstroms. In an alternative embodiment, the stressed layer 130 may be formed of silicon carbide (SiC).

As described above, conventional fabrication methods typically utilize a plasma enhanced chemical vapor deposition (PECVD) process to deposit prior art CESLs. These conventional CESLs are deposited on the transistor contact area of the S/D regions 128, and may include silicon nitride having a specified internal stress. As is known, the deposition parameters (e.g., pressure, temperature, bias voltage and the like) during the PECVD process for depositing the silicon nitride may be selected to provide the desire stress (tensile or compressive, and magnitude). The stressed layer 130 of the present disclosure is formed in accordance with a different process, as described more fully below.

Stressed layer 130 is a dielectric film formed in accordance with a spin-on dielectric (SOD) process. Spin-on materials exhibiting good etch selectivity and high shrinkage characteristics or qualities may be utilized, including those in which silicon nitride or silicon carbide are formed after a curing process. In one embodiment, the dielectric is a polysilazane-based dielectric that is spun onto the semiconductor wafer. One example of a polysilazane-based dielectric that may be utilized is perhydro-polysilazane ((SiH₂NH)ₙ). This material is applied and spun-on at room temperature (approximately 18 to 24 degrees Celsius) and then subjected to a heating process (i.e., baked) at a temperature between about 100 and 200 degrees C. in air for between 1 to 15 minutes to form a dielectric film.

In another embodiment, the stressed layer 130 may be silicon carbide (SiC) and the spin-on dielectric may be based on a polyimide or polycarbonate material or composition. Similar processing steps, such as those described herein, may be used to form such a SiC stressed layer. Though the title of this application refers to silicon nitride and one specific description of the process of forming this layer (and nFET structure with this layer), as noted, the stressed layer 130 may be formed of silicon carbide, and possibly other spin-on materials that have good etch selectivity and high shrinkage. Furthermore, the device region 110 is described as an nFET structure, however, this structure may be a pFET structure in certain applications.

After the baking step, the film is subjected to a high temperature (thermal) curing process in a nitrogen gas (N2) environment. The wafer (structure) is cured at a temperature ranging between 200 and 500 degrees C. for between 30 to 60 minutes. The solvent is driven off, and water is evolved from the film (due to polymerization of the silanol [SiOH] groups). The loss of considerable mass together with material shrinkage creates a tensile stress in the film. High temperature curing at a temperature above 200 degrees C. removes all or most of the hydrogen and promotes film re-structuring into silicon nitride (SiₓN_{y}). In one particular embodiment, the structure is heated to about 450 degrees C.

Since the original spin-on film includes a substantial number of Si—H bonds, a large amount of hydrogen will be removed as a result of the high temperature curing. This causes a substantial amount of shrinkage in the CESL 130 (more than PECVD film) and leads to an increase in the stress gain. Thus, the foregoing described process including the steps of forming a SiN CESL using a spin-on polysilazane-based dielectric, baking, and curing produces an SiN CESL (stress film) having increased stress as compared to an SiN stress film fabricated using conventional PECVD. The higher stress of the SiN CESL 130 generates (applies or introduces) a higher tensile stress to the channel region, thus enhancing carrier mobility of the nFET structure 120.

In addition to thermal curing, the curing step may involve ultra-violet (UV) curing, electron beam curing, laser curing and the like and/or an equivalent high power treatment to remove hydrogen from the spun-on dielectric and cause re-crystallization to promote film shrinkage and stress gain in the CESL 130.

For UV curing, the process may include a wavelength of between about 200 nm and about 500 nm, a UV energy of between about 5000 W/m₂ and about 1500 W/m₂, a substrate temperature of between about 250 degrees C. and about 500 degrees C., a treatment time of between about 2 minutes and about 15 minutes, and process gases including helium, nitrogen, argon, ozone, carbon dioxide and/or normal air. In general terms, any curing process or method that removes hydrogen and causes restructuring may be utilized.

The CESL 130 causes a resulting tensile stress to be applied to the channel region 129. Since this is generally undesirable for pFET structures, the CESL 130 may be selectively formed (i.e., selective formation or removal) over nFET structures, or the CESL 130 may be formed over both nFET and pFET structures with the portions of the CESL 130 formed over pFET structures further treated, as described above or known to those skilled in the art, to reduce its stress.

Though CESL 130 is shown as a single layer, in another embodiment, the steps of spin-on deposition of the polysilazane-based dielectric, baking and curing may be repeated one or more times to provide a multi-layer CESL 130 (not shown). Since SOG is subject to cracking at a single deposition thickness around 1500 Angstroms or greater, and since the increase stress induced by the foregoing process may also increase possible cracking, forming the CESL 130 in multiple layers may be beneficial and help reduce the likelihood of cracking in the film. This may be particularly applicable when the SiN stress layer formed by the process described herein is utilized as a capping layer in a stress memorization technique (SMT) instead of use as a CESL. In such SMT, the thickness may be increased above 1000 Angstroms in order to increase the memorization stress induced into the gate structure and transferred to the channel region.

After the stressed layer 130 is formed (as described above), the source/drain (S/D) substrate area 128 and gate structure (122, 124, 126) are amorphized, as described in the prior art, by implantation of a dopant. Conventional dopant activation annealing is then performed. The stress effect is transferred from the silicon nitride stressed layer 130 to the channel 129 during the annealing process and the re-crystallization of the S/D and gate structure causes memorization of the stress induced in the stressed layer 130. This stress is retained and applied to the channel region 129. In various embodiments, the stressed capping layer 130 may remain or may be removed.

In general terms, the present disclosure provides a process (and resulting structure) in which a dielectric material is spun-on the substrate to form a silicon nitride stress layer (to function as either a CESL or capping layer for use in an SMT) to increase the tensile stress in the channel to enhance transistor performance.

The order of steps or processing can be changed or varied form that described above. It will be understood that well known processes have not been described in detail and have been omitted for brevity. Although specific steps, insulating materials, conductive materials and apparatuses for depositing and etching these materials may have been described, the present disclosure may not be limited to these specifics, and others may substituted as is well understood by those skilled in the art.

It may be advantageous to set forth definitions of certain words and phrases used throughout this patent document. The terms “include” and “comprise,” as well as derivatives thereof, mean inclusion without limitation. The term “or” is inclusive, meaning and/or. The phrases “associated with” and “associated therewith,” as well as derivatives thereof, mean to include, be included within, interconnect with, contain, be contained within, connect to or with, couple to or with, be communicable with, cooperate with, interleave, juxtapose, be proximate to, be bound to or with, have, have a property of, or the like.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method of forming a semiconductor structure, the method comprising:
providing a substrate;
forming a stressed layer overlying the substrate for applying tensile stress to a channel region of an n-type field effect transistor (FET), wherein forming the stressed layer comprises,
spin-on deposition of a dielectric material on the substrate,
heating the dielectric material to form a dielectric film, and
curing the dielectric film to shrink the dielectric film thereby forming the stressed layer.

2. The method in accordance with claim 1 wherein the stressed layer forms a contact etch stop layer (CESL).

3. The method in accordance with claim 1 wherein the stressed layer forms a capping layer for applying tensile stress to the channel region in accordance with a stress memorization technique.

4. The method in accordance with claim 1 wherein heating the dielectric material includes heating to a temperature between about 100 and 200 degrees Celsius.

5. The method in accordance with claim 1 wherein curing the dielectric film to form the stressed layer further comprises:
removing a substantial portion of an element from the dielectric material to cause shrinkage in the dielectric film.

6. The method in accordance with claim 5 wherein curing the dielectric film to form the stressed layer further comprises a one of: thermal curing, ultra-violet (UV) curing, electron beam curing and laser curing.

7. The method in accordance with claim 1 wherein the dielectric material has good etch selectivity and high shrinkage characteristics.

8. The method in accordance with claim 7 wherein the dielectric material comprises polysilazane.

9. The method in accordance with claim 7 wherein the dielectric material is perhydro-polysilazane.

10. The method in accordance with claim 1 wherein the stressed layer applies a tensile stress to the channel region of at least about 1.7 Gpa.

11. A semiconductor substrate having one or more field effect transistors (FETs), the substrate comprising:
a first n-type FET having a source region, a drain region and a gate structure; and
a stressed film overlying the source region, the drain region and the gate structure, the stressed film imparting a tensile stress of at least about 1.7 Gpa within a channel region extending between the source region and the drain region.

12. The substrate in accordance with claim 11 wherein the stressed film functions as a contact etch stop layer (CESL) and comprises silicon nitride formed from a dielectric material spun onto the substrate.

13. The substrate in accordance with claim 11 wherein the stressed film functions as a capping layer to impart the tensile stress through a stress memorization technique and comprises silicon nitride formed from a dielectric material spun onto the substrate.

14. The substrate in accordance with claim 11 wherein the stressed film is formed from polysilazane deposited on the substrate.

15. A method of forming a stressed layer for generating tensile stress within a channel region of a field-effect transistor (FET) in a semiconductor structure, the method comprising:
spinning on a dielectric material over a gate structure, a source region and a drain region of a FET;
heating the dielectric material to form a dielectric film, and
curing the dielectric film to shrink the dielectric film thereby forming the stressed layer.

16. The method in accordance with claim 15 wherein the stressed layer forms a contact etch stop layer (CESL), and the CESL imparts tensile stress to a channel region of the FET.

17. The method in accordance with claim 16 wherein the stressed layer has a thickness less than about 750 Angstroms.

18. The method in accordance with claim 15 wherein the stressed layer forms a capping layer for applying tensile stress to a channel region of the FET in accordance with a stress memorization technique.

19. The method in accordance with claim 15 wherein the dielectric material is perhydro-polysilazane, and curing the dielectric film to form the stressed layer further comprises:
removing a substantial portion of hydrogen from the dielectric material to cause shrinkage in the dielectric film.

20. The method in accordance with claim 15 wherein the stressed layer is formed of multiple layers of dielectric material, with each layer formed by:
spinning on the dielectric material over the gate structure, the source region and the drain region of the FET;
heating the dielectric material to form the dielectric film, and
curing the dielectric film to shrink the dielectric film thereby forming one of the multiple layers of the stressed layer.
